(19) United States
(12) Patent Application Publication
(10) Pub. No.: US 2014/0232998 A1
(43) Pub. Date: Aug. 21, 2014

(54) SEMICONDUCTOR MANUFACTURING APPARATUS AND MANUFACTURING METHOD OF SEMICONDUCTOR DEVICE

(71) Applicant: Kabushiki Kaisha Toshiba, Minato-ku (JP)

(72) Inventor: Koutarou SHO, Yokkaichi-Shi (JP)

(73) Assignee: Kabushiki Kaisha Toshiba, Minato-ku (JP)

(21) Appl. No.: 14/019,773

(22) Filed: Sep. 6, 2013

(30) Foreign Application Priority Data
Feb. 20, 2013 (JP) 2013-031327

(51) Int. Cl. H01L 21/02

(52) U.S. Cl. CPC H01L 21/02041
USPC 355/30

(57) ABSTRACT

A semiconductor manufacturing apparatus according to the present embodiment comprises a vacuum chamber. A first stage is configured to temporarily attach a reticle thereonto in order to attract a foreign material present on a back surface of the reticle. A second stage is configured to attach the reticle thereonto after attaching the reticle onto the first stage in order to expose a semiconductor substrate to light using the reticle within the vacuum chamber. An exposure unit is configured to expose a surface of the semiconductor substrate to the light using the reticle attached onto the second stage.

### CROSS REFERENCE TO RELATED APPLICATIONS

This application is based upon and claims the benefit of priority from the prior Japanese Patent Application No. 2013-031327, filed on Feb. 20, 2013, the entire contents of which are incorporated herein by reference.

### FIELD

The embodiments of the present invention relate to a semiconductor manufacturing apparatus and a manufacturing method of a semiconductor device.

### BACKGROUND

Development of an exposure apparatus using EUV (Extreme Ultra Violet) light (hereinafter, also “EUV exposure apparatus”) is underway so as to form downscaled semiconductor devices. The EUV exposure apparatus uses a reflection optical system because the refraction index of the EUV light is nearly one. As the reflection optical system, EUV exposure apparatus uses not a transmission reticle but a reflection reticle. Furthermore, because of the attenuation of the EUV light in the air, the interior of the chamber of the EUV exposure apparatus is kept in a vacuum. The EUV exposure apparatus uses an electrostatic chuck for fixing the reticle within the vacuum chamber because a vacuum chuck is unable to attract the reticle.

However, when a foreign material is present on a reticle stage, the surface of the reticle is distorted because the electrostatic chuck attracts the reticle in a state where the foreign material is put between the reticle stage and the reticle. When the EUV exposure apparatus performs exposure in a state where the surface of the reticle is distorted, the defocusing and misalignment of a circuit pattern to be transferred occur. Such a foreign material is considered to be dust or the like entering the vacuum chamber when the reticle is transported from a load lock chamber into the vacuum chamber.

To remove the foreign material on the reticle stage, it is necessary to release the vacuum state of the chamber of the EUV exposure apparatus to release the interior of the chamber to the atmospheric pressure. This results in a long downtime since stopping the EUV exposure apparatus until reactivating the EUV exposure apparatus. Accordingly, it is impossible to remove the foreign material on the reticle stage instantly or frequently.

### BRIEF DESCRIPTION OF THE DRAWINGS

FIG. 1 is an example of a configuration of an EUV exposure apparatus 100 according to a first embodiment;

FIG. 2 is a flowchart showing an exposure method using the EUV exposure apparatus 100 according to the first embodiment; and

FIG. 3 is an example of a configuration of the EUV exposure apparatus 100 according to a second embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor manufacturing apparatus according to the present embodiment comprises a vacuum chamber. A first stage temporarily attaches a reticle thereonto in order to attract a foreign material present on a back surface of the reticle. A second stage attaches the reticle thereonto after attaching the reticle onto the first stage in order to expose a semiconductor substrate to light using the reticle within the vacuum chamber. An exposure part exposes a surface of the semiconductor substrate to the light using the reticle attached onto the second stage.

### First Embodiment

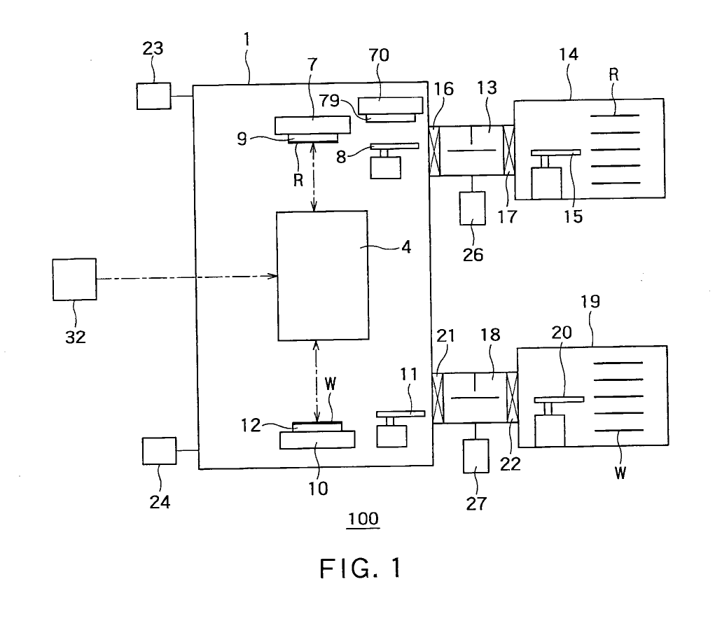

FIG. 1 is an example of a configuration of an EUV exposure apparatus 100 according to a first embodiment. The EUV exposure apparatus 100 includes a vacuum chamber 1, a particle attraction stage 70 serving as a first stage, a reticle stage 7 serving as a second stage, a wafer stage 10, electromagnetic chucks 9 and 12, an optical system 4 serving as an exposure part, a reticle transport arm 8, a wafer transport arm 11, a controller 23, and a vacuum device 24.

The vacuum device 24 keeps the interior of the vacuum chamber 1 in a vacuum (a reduced-pressure atmosphere of about 1×10⁻⁴ Pa, for example). The reticle stage 7, the wafer stage 10, and the optical system 4 are provided within the vacuum chamber 1 and exposure using EUV light is executed within the vacuum chamber 1. In the first embodiment, a particle attraction stage 70 is also provided in the vacuum chamber 1. For example, EUV light is light having a wavelength range of 13 to 14 nm.

The reticle stage 7 includes the electromagnetic chuck 9 and a reflection reticle R on which a circuit pattern is formed is attached onto the reticle stage 7 so as to expose a semiconductor substrate W to the EUV light. The electromagnetic chuck 9 attracts and fixes the reticle R. The reticle stage 7 is provided to be movable in a scanning direction during the exposure.

The wafer stage 10 includes the electromagnetic chuck 12 and the semiconductor substrate W that is an exposure target is mounted on the wafer stage 10. The wafer stage 10 is provided to be movable in the scanning direction during the exposure.

The particle attraction stage 70 temporarily attaches the reticle R thereonto so as to attract a particle present on a back surface of the reticle R. The particle attraction stage 70 can be configured similarly to the reticle stage 7 and includes an electromagnetic chuck 79. The electromagnetic chuck 79 of the particle attraction stage 70 is preferably a unipolar electromagnetic chuck. This is because the unipolar electromagnetic chuck can effectively remove the particle from the back surface of the reticle R because of a high attraction force at a low voltage and no height difference on an attraction surface.

Furthermore, a reticle attachment surface of the particle attraction stage 70 can be formed out of either an adhesive material or an elastic material. For example, the reticle attachment surface of the particle attraction stage 70 can be formed out of a polymer-based insulating film. The particle on the back surface of the reticle R thereby adheres onto the adhesive material of the particle attraction stage 70. Alternatively, the particle on the back surface of the reticle R is buried in the elastic material of the particle attraction stage 70 and removed. The reticle R is attached onto the reticle stage 7 after being temporarily attached onto the particle attraction stage 70 by the reticle transport arm 8. Therefore, it is necessary to suppress adhesive power of the adhesive material of the particle attraction stage 70 to be low to such an extent that the particle attraction stage 70 can capture the particle and that the reticle R can be unloaded from the particle attraction stage 70 by its own weight of the reticle R when the electromagnetic chuck 79 does not operate. The reticle stage 7 and the particle attraction stage 70 include the electromagnetic chucks 9 and 79 on back surfaces thereof, respectively, and the reticle R is attached onto the back surface of each of the reticle stage 7 and the particle attraction stage 70.

It is also preferable that the reticle attachment surface of the particle attraction stage 70 is formed as a single surface without being divided and without any difference in height. That is, the particle attraction stage 70 is preferably a full flat stage. The reticle attachment surface of the particle attraction stage 70 can contact the entire back surface of the reticle R and capture the particle on the entire back surface of the reticle R.

The particle attraction stage 70 can be made either movable similarly to the reticle stage 7 or fixed to the vacuum chamber 1.

The reticle transport arm 8 carries the reticle R from a load lock chamber 13 into the vacuum chamber 1 and transports the carried reticle R onto the particle attraction stage 70. After removing the particle on the back surface of the reticle R on the particle attraction stage 70, the reticle transport arm 8 carries the reticle R onto the reticle stage 7.

The load lock chamber 13 is provided so as to receive and deliver the reticle R between a reticle exchange chamber 14 and the vacuum chamber 1. A vacuum device 26 can make the interior of the load lock chamber 13 into a vacuum state. Gate valves 16 and 17 are provided on both sides of the load lock chamber 13, respectively. When the load lock chamber 13 receives the reticle R from the reticle exchange chamber 14, the gate valve 16 is closed and the gate valve 17 is opened. At this time, an internal pressure of the load lock chamber 13 is equal to the atmospheric pressure. On the other hand, when the load lock chamber 13 carries the reticle R into the vacuum chamber 1, the gate valve 17 is closed and the gate valve 16 is opened. After closing the gate valve 17 and before the opening the gate valve 16, the vacuum device 26 makes the interior of the load lock chamber 13 into the vacuum state.

The reticle exchange chamber 14 accommodates a plurality of reticles R. A reticle transport arm 15 receives and delivers the reticle R between the reticle exchange chamber 14 and the load lock chamber 13.

The wafer transport arm 11 carries the semiconductor substrate W from a load lock chamber 18 into the vacuum chamber 1 and mounts the carried semiconductor substrate W onto the wafer stage 10.

The load lock chamber 18 is provided so as to receive and deliver the semiconductor substrate W between a wafer exchange chamber 19 and the vacuum chamber 1. A vacuum device 27 can make the interior of the load lock chamber 18 into a vacuum state. Gate valves 21 and 22 are provided on both sides of the load lock chamber 18, respectively. When the load lock chamber 18 receives the semiconductor substrate W from the wafer exchange chamber 19, the gate valve 21 is closed and the gate valve 22 is opened. At this time, an internal pressure of the load lock chamber 18 is equal to the atmospheric pressure. On the other hand, when the load lock chamber 18 carries the semiconductor substrate W into the vacuum chamber 1, the gate valve 22 is closed and the gate valve 21 is opened. After closing the gate valve 22 and before the opening the gate valve 21, the vacuum device 27 makes the interior of the load lock chamber 18 into the vacuum state.

The wafer exchange chamber 19 accommodates a plurality of semiconductor substrates W. A wafer transport arm receives and delivers the semiconductor substrate W between the wafer exchange chamber 19 and the load lock chamber 18.

An EUV light source 32 generates the EUV light and supplies the EUV light to the optical system 4. The optical system 4 exposes the semiconductor substrate W to the EUV light and transfers the circuit pattern formed on the reticle R attached onto the reticle stage 7 onto the semiconductor substrate W mounted on the wafer stage 10. During the exposure, the optical system 4 irradiates the EUV light onto the reticle R and exposes the semiconductor substrate W to the exposure light (EUV light) reflected by the reticle R. That is, the optical system 4 performs irradiation of the EUV light onto the reticle R and projection of an image onto the semiconductor substrate W. A photosensitive material (a resist, for example) is applied onto a surface of the semiconductor substrate W in advance, and the photosensitive material on the semiconductor substrate W is exposed to the exposure light. The optical system 4 executes the exposure while scanning the reticle stage 7 and the wafer stage 10 in the scanning direction.

The controller 23 controls operations performed by respective constituent elements of the EUV exposure apparatus 100 such as the particle attraction stage 70, the reticle stage 7, and the wafer stage 10. For example, the controller 23 controls a mask position based on a measurement result of a laser interferometer (not shown) and a detection result of a focus leveling detection system (not shown).

The EUV exposure apparatus 100 according to the first embodiment includes a plurality of stages (the reticle stage 7 and the particle attraction stage 70) onto which the reticle R is attached. The reticle R attached onto the reticle stage 7 is thereby less distorted because the particle on the back surface of the reticle R is removed on the particle attraction stage 70. The less distortion of the reticle R can decrease defocusing, overlay errors, and the like.

Moreover, the unipolar electromagnetic chuck is stronger in attraction power than a bipolar electromagnetic chuck. Therefore, when the electromagnetic chuck 79 is the unipolar electromagnetic chuck, the particle on the back surface of the reticle R can be not only attracted by the particle attraction stage 70 but also squashed between the particle attraction stage 70 and the reticle R. Therefore, it is advantageous that the reticle R has a less distortion when the reticle R is attached onto the reticle stage 7 even if the particle remains on the back surface of the reticle R.

In the first embodiment, the particle attraction stage 70 is provided inside of the vacuum chamber 1. In this case, the particle attraction stage 70 is preferable in that the particle attraction stage 70 can capture the particle adhering when the reticle R is carried into the vacuum chamber 1. However, the particle attraction stage 70 can be provided outside of the vacuum chamber 1. For example, the particle attraction stage 70 can be provided in the load lock chamber 18 or the reticle exchange chamber 14. In this case, it is advantageous to be able to facilitate cleaning the particle attraction stage 70. When the particle attraction stage 70 is provided within the load lock chamber 18, the particle attraction stage 70 receives the reticle R from the reticle transport arm 15, captures the particle, and then delivers the reticle R to the reticle transport arm 8. It is thereby possible to smoothly transport the reticle R.

Furthermore, the particle attraction stage 70 can also function to transport the reticle R between the vacuum chamber 1 and the reticle exchange chamber 14. In other words, the reticle transport arm 8 or 15 can function as the particle attraction stage 70. In this case, it is advantageous to be able to make the configuration of the EUV exposure apparatus 100 simpler and to realize cost reduction in addition to facilitating cleaning the particle attraction stage 70.

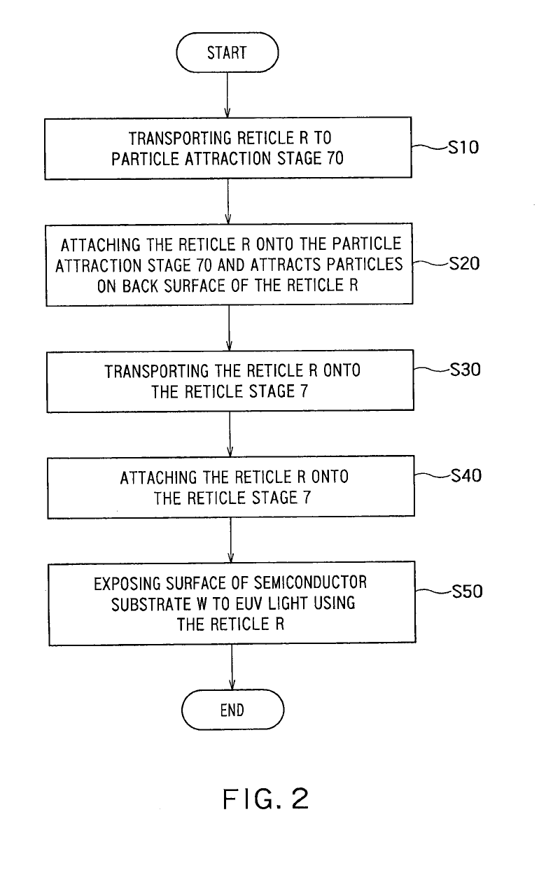

FIG. 2 is a flowchart showing an exposure method using the EUV exposure apparatus 100 according to the first embodiment. First, the reticle transport arm 8 transports the reticle R to be used for the exposure to the particle attraction stage 70 (S10). The reticle R is temporarily attached onto the particle attraction stage 70 by the electromagnetic chuck 79 and the particle attraction stage 70 thereby attracts the particle on the back surface of the reticle R (S20). Alternatively, the particle attraction stage 70 squashes the particle on the back surface of the reticle R.

Next, the reticle transport arm 8 transports the reticle R from the particle attraction stage 70 onto the reticle stage 7 (S30). The reticle R is attached onto the reticle stage 7 (S40).

Thereafter, the optical system 4 exposes the surface of the semiconductor substrate W to the EUV light using the reticle R (S50).

The EUV exposure apparatus 100 can thereby decrease the distortion of the reticle R and decrease exposure errors such as the defocusing and the overlay errors.

### Second Embodiment

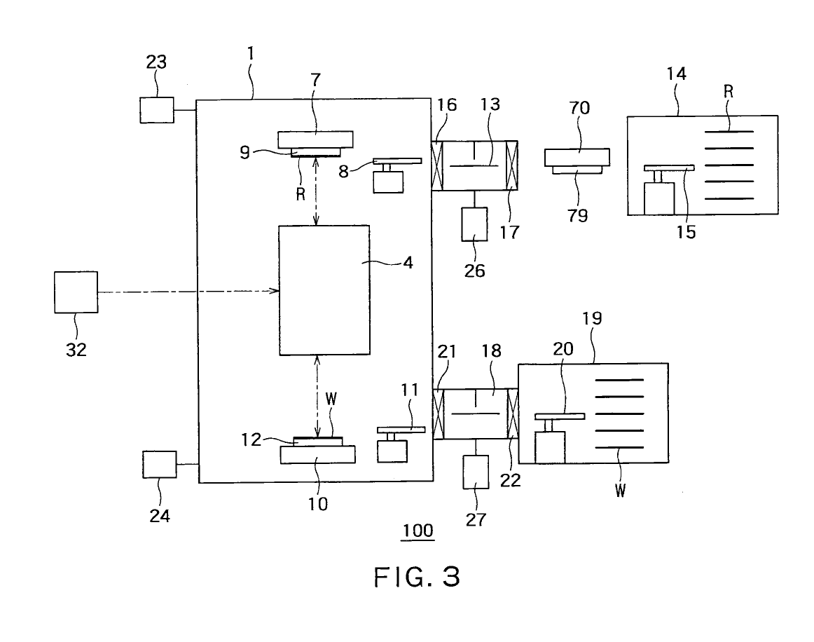

FIG. 3 is an example of a configuration of the EUV exposure apparatus 100 according to a second embodiment. The EUV exposure apparatus 100 according to the second embodiment includes a plurality of reticle stages, and each of the reticle stages is used to expose the semiconductor substrate W to the EUV light using the reticle R within the vacuum chamber 1. The second embodiment is explained while assuming that the reticle stages 7 and 70 correspond to a plurality of reticle stages.

Each of the reticle stages 7 and 70 is transported to outside of the vacuum chamber 1 while mounting thereon the reticle R after being used for the exposure in a state of attaching the reticle R onto the reticle stage 7 or 70 within the vacuum chamber 1. That is, each of the reticle stages 7 and 70 itself is moved to the outside of the vacuum chamber 1 (into the reticle exchange chamber 14, for example) integrally with the reticle R. In this case, it is unnecessary to provide the reticle transport arm 8. A mechanism for moving each of the reticle stages 7 and 70 itself to the outside of the vacuum chamber 1 can be realized by applying wafer stages of a so-called dual-stage exposure apparatus to the reticle R.

While the first reticle stage 7 out of the reticle stages 7 and 70 is used for exposing the semiconductor substrate W to the EUV light within the vacuum chamber 1, the second reticle stage 70 out of the reticle stages 7 and 70 is cleaned outside of the vacuum chamber 1 and the reticle R used for the next exposure is attached onto the reticle stage 70. After the end of the exposure using the first reticle stage 7, the first reticle stage 7 is moved to the outside of the vacuum chamber 1 and the second reticle stage 70 onto which the next reticle R is attached is moved into the vacuum chamber 1. The next exposure is executed using the second reticle stage 70. While the second reticle stage 70 is used for exposing the semiconductor substrate W to the EUV light within the vacuum chamber 1, the first reticle stage 7 is cleaned outside of the vacuum chamber 1 and the reticle R used for the next exposure is attached onto the first reticle stage 7. In this way, in the second embodiment, the reticle stages 7 and 70 include the identical function and alternately repeat the exposure inside of the vacuum chamber 1 and the cleaning and reticle exchange outside of the vacuum chamber 1.

According to the second embodiment, it is possible to easily clean the reticle stages 7 and 70 while keeping the vacuum chamber 1 in a vacuum because the reticle chambers 7 and 70 are movable to the outside of the vacuum chamber 1.

Furthermore, each of the reticle stages 7 and 70 is moved into the vacuum chamber 1 in a state of attaching the reticle R onto the reticle stage 7 or 70. Therefore, it is difficult for the particle to adhere onto the back surface of the reticle R when transporting the reticle R into the vacuum chamber 1.

As a result, the second embodiment can effectively reduce the foreign material adhering onto the reticle or the foreign material adhering onto the reticle stage similarly to the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a vacuum chamber;
a first stage temporarily attaching a reticle thereonto in order to attract a foreign material present on a back surface of the reticle;
a second stage attaching the reticle thereonto, after attaching the reticle onto the first stage, in order to expose a semiconductor substrate to light using the reticle within the vacuum chamber; and
an exposure part exposing a surface of the semiconductor substrate to the light using the reticle attached onto the second stage.

2. The apparatus of claim 1, wherein a reticle attachment surface of the first stage is formed using a polymer-based insulating film.

3. The apparatus of claim 1, wherein the first and second stages respectively include electrostatic chucks for attaching the reticle thereonto.

4. The apparatus of claim 3, wherein the first stage includes a unipolar electrostatic chuck.

5. The apparatus of claim 1, wherein the first stage is provided outside of the vacuum chamber.

6. The apparatus of claim 1, wherein the first stage is provided inside of the vacuum chamber.

7. The apparatus of claim 1, the first stage transports the reticle between inside and outside of the vacuum chamber.

8. A semiconductor manufacturing apparatus comprising:
a vacuum chamber;
a plurality of stages capable of attaching reticles thereonto in order to expose a semiconductor substrate to light using the reticles within the vacuum chamber; and
an exposure part exposing a surface of the semiconductor substrate to the light using the reticles attached onto the stages, respectively, wherein
the stages are respectively transported to outside of the vacuum chamber while mounting the reticle onto the stages after being used for exposure with the reticles attached onto the stages within the vacuum chamber.

9. A manufacturing method of a semiconductor device using a semiconductor manufacturing apparatus including a vacuum chamber, a plurality of stages capable of attaching a reticle thereonto, and an exposure part exposing a surface of the semiconductor substrate to light using the reticle, the method comprising:
removing a foreign material present on a back surface of the reticle by temporarily attaching the reticle onto a first stage among the stages;
attaching the reticle onto a second stage among the stages after attaching the reticle onto the first stage; and
exposing the surface of the semiconductor substrate to the light using the reticle.

10. The method of claim 9, wherein the first stage captures the foreign material present on the back surface of the reticle using an adhesive material or an elastic material.

11. The method of claim 9, wherein the first stage squashes the foreign material present on the back surface of the reticle.

12. The method of claim 10, wherein the first stage squashes the foreign material present on the back surface of the reticle.
